(19) United States
(12) Patent Application Publication
(10) Pub. No.: US 2023/0419006 A1
(43) Pub. Date: Dec. 28, 2023

(54) SMART FEEDBACK DESIGN FOR VERIFICATION

(71) Applicant: ATI TECHNOLOGIES ULC, MARKHAM (CA)

(72) Inventor: David Akselrod, Hamilton (CA)

(21) Appl. No.: 17/846,341

(22) Filed: Jun. 22, 2022

(51) Int. Cl. G06F 30/3308; G06F 30/27

(52) U.S. Cl. CPC G06F 30/3308; G06F 30/27

(57) ABSTRACT

Techniques for implementing a smart feedback design for verification that reduce production and verification time by enabling a verification system to perform piecemeal verification of components of a circuit design selectively, accurately, and exhaustively before a final, overall circuit design is completed are disclosed. Circuit nodes in an emulation model are selected and smart feedback is provided to the nodes in response to signals detected at the nodes such that behavior of unavailable or unverified components to be located at the nodes can be simulated. Smart feedback can be provided to the node to enable verification of the emulation model without having to wait for the unverified or unavailable components to be provided or verified. A request for manufacture may be generated including aspects of the emulation model to enable verification of a fabricated circuit in a similar or identical manner to those used to verify the emulation model.

### BACKGROUND

Integrated circuit development involves pre-manufacturing verification during which the operation of one or more portions of the integrated circuit are simulated using one of EDA simulation tools (e.g., Verilog simulations), as well as emulated, and one or more resulting outputs are compared to a set of expected results. However, verification engineers typically must wait until the designs of all the various components of the integrated circuit are complete to perform comprehensive verification, which can cause severe delays in verifying the operation of the integrated circuit and, particularly when verification fails, can severely delay production goals, result in missed deadlines and further manufacturing delays, and otherwise negatively impact the production cycle. Often, after a problem is identified in verification, multiple design teams need to be involved in identifying and remediating the problem, which increases costs and causes further delays. Additionally, even after a problem is remediated, further verification of the entire circuit must be performed to ensure that the remediation of the identified problem does not result in other problems. Accordingly, the verification process typically consumes a large amount of time and resources, especially as integrated circuit designs become more complex and involve increasing numbers of contractors, subcontractors, and suppliers.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a smart feedback emulation model in accordance with some embodiments.

FIG. 2 is a flow diagram illustrating a method for providing smart feedback in accordance with some embodiments.

FIG. 3 is a block diagram of a request for manufacture in accordance with some embodiments.

FIG. 4 is a block diagram of a smart feedback circuit in accordance with some embodiments.

### DETAILED DESCRIPTION

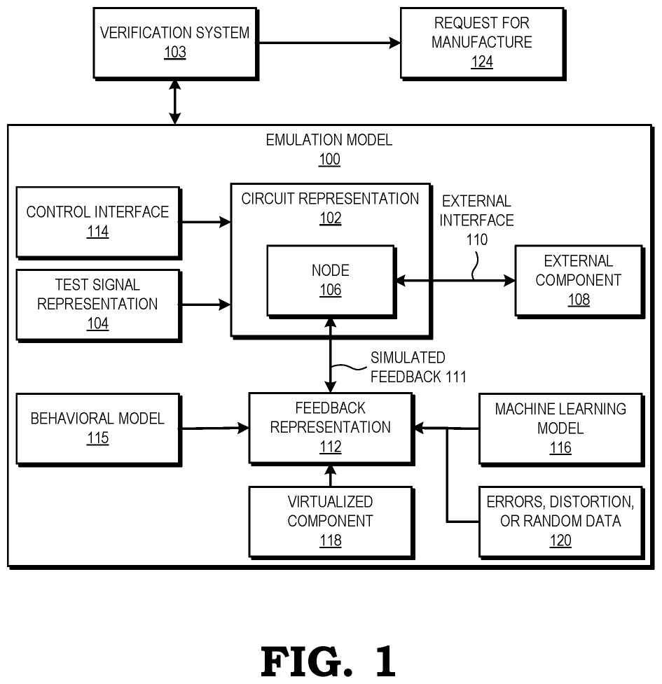

FIGS. 1-4 illustrate techniques for implementing a smart feedback design for verification that reduces production and verification time by enabling verification engineers to perform individual verification of components or portions of a circuit design selectively, accurately, and exhaustively before a final, overall circuit design is completed. In addition to streamlining verification by emulating and/or bypassing selected circuit elements, the techniques described herein are, in some embodiments, used to verify operation of a circuit design prior to or after fabrication in an isolated manner such that operation of individual portions of a circuit are validated before attempting to validate a full circuit design. Thus, rather than having to test an entire circuit at the end of a design cycle and, in case problems are identified, using a top-down approach to identify the source of the problem, which is an unwieldy and expensive exercise, aspects of the present disclosure enable a bottom-up approach wherein individual elements of a circuit are partially or fully validated before attempting to validate larger groups of components or the full circuit design. Although aspects of the present disclosure may add nontrivial costs to a fabricated circuit, the time and cost savings resulting from being able to perform efficient verification and troubleshooting will often outweigh the additional costs of fabrication.

To illustrate, in some embodiments, circuit nodes in an emulation model are selected and smart feedback is provided to the nodes in response to signals detected at the nodes. In this way, behavior of unavailable or unverified components to be located at the nodes are simulated and smart feedback is provided to the node to enable verification of the emulation model without having to wait for the unverified or unavailable components to be provided or verified. In some embodiments, a request for manufacture is generated including aspects of the emulation model to enable verification of a fabricated circuit in a similar or identical manner to those used to verify the emulation model.

To illustrate further via an example, in some verification scenarios, it is desirable to verify the operation of an input/output (I/O) module of an integrated circuit design, and in particular the operation of an I/O module as it negotiates a communication session with an external component (that is, a component external to the integrated circuit, such as another integrated circuit). Conventionally, to verify the operation of the I/O module, a verification system emulates the operation of both the I/O module and the external component. However, this requires a complete emulation model of the external component, which increases the time and complexity associated with the verification process. Using the techniques herein, the operation of the external component is not fully emulated. Instead, the verification system employs a feedback representation to emulate the required communications from the external component to the I/O module. Because the feedback representation does not emulate all operations of the external component itself, the feedback representation is able to be developed and adjusted relatively quickly, reducing the time and complexity of the verification process.

Aspects of the present disclosure are directed to pre-manufacture verification, emulation, and on-chip post-fabrication operation and verification. In some embodiments, a smart feedback design for verification is presented and applied to inter-module, inter-core, inter-chiplet, and/or inter-chip pre-manufacture verification, emulation, or post-fabrication operation or verification. Using aspects of the present disclosure, in some embodiments, smart feedback provided to a selected node in a circuit is identical to feedback the node would receive from an unavailable or unverified component. Accordingly, in some embodiments, rather than merely redirecting data or returning identical data, the operation of an unavailable or unverified component is simulated such that verification can be performed at any point in the design process without delay.

FIG. 1 illustrates an example of a smart feedback emulation model 100 implemented in accordance with some embodiments for verifying a circuit such as that stored in a circuit representation 102. In some embodiments, the circuit is stored in the form of a netlist, which is a description of the components and connectivity of an electronic circuit. In some embodiments, the circuit is stored in the form of register-transfer level (RTL), which is a description of the components and connectivity of an electronic circuit. In order to verify expected operation of the circuit representation 102, a verification system 103 under the control of a verification engineer simulates the application of a test signal such as that stored in a test signal representation 104 to one or more nodes, or connection points, of the circuit representation 102 in the emulation model 100. In some embodiments, the verification system 103 is a computing device or test bench including a processor, memory, and input/output interfaces (not shown) that enable a verification engineer to interface with, test, and/or manipulate the emulation model 100. In some embodiments, components of the verification system 103 test operation of fabricated circuits in addition to emulation models. Generally, the verification system 103 includes any hardware or software needed to simulate and verify an emulation model and/or to verify a fabricated circuit in accordance with the present disclosure.

By analyzing output data of the circuit representation 102 that is generated in response to the test signal representation 104 and often other characteristics of the performance of the circuit representation 102 the simulation provides (e.g., thermal characteristics and electromagnetic characteristics, among others), the verification system 103 determines whether the circuit representation 102 accurately performs its intended function. However, modern chip design often requires a complex orchestration of vendors, engineers, designers, and contractors in order to meet deadlines, and so verification of a final circuit design typically must wait until every single component of a design (e.g., a number of multi-chip modules or chiplets) is complete. After receiving a final circuit design, a verification engineer must then run simulations using the verification system 103 of the entire circuit in order to ensure proper operation, which often involves careful arrangement of data stored in thousands of files. Once the final circuit is ready for verification simulation, due to the complexity of modern designs, the verification engineer still often must wait up to a week for the verification system 103 to simulate a few milliseconds of simulation inputs. For this reason, verification often causes undesirable delays in production, particularly when one or more components are only available to the verification engineer at or near the end of the design phase.

In order to reduce the effects of the bottleneck created by delays in receiving final designs for various components, in accordance with aspects of the present disclosure, the verification engineer and/or verification system 103 identifies one or more nodes, such as the node 106 of the circuit representation 102, where the circuit representation 102 will interface with an external component 108, such as a multi-chip module, a communication interface, or any other aspect of a final circuit design, via an external interface 110 located at the node 106. Although the external component 108 and external interface 110 are shown in FIG. 1 and described herein as “external” to circuit representation 102, the external component 108 and external interface 110 represent any component and interface that is unavailable to the verification system 103 at a given time. For example, in some embodiments, the circuit representation 102 is of a processor and the external component 108 is a co-processor (such as a graphics processing unit, a machine learning processor, or an application-specific integrated circuit) or a cache. As another example, in some embodiments, the circuit representation 102 is of a cache and the external component 108 represents a number of devices connected with a bus that utilize the cache. Accordingly, in some embodiments, the external interface 110 is an intra-die, inter-die, stack-to-stack, or socket-to-socket interface that connects the circuit representation 102 with one or more other representations of multi-chip modules, chiplets, cores, modules, or other components. Thus, in some embodiments, a final circuit design includes the circuit of circuit representation 102, the external component 108, and the external interface 110. However, in other embodiments, a final circuit design includes only the circuit of circuit representation 102 and a portion of the external interface 110 (such as a port, a pin, or a communications module) such that the external component 108 is external to a final circuit design. As such, the term “external” in external component 108 and external interface 110 is understood to mean components and/or interfaces that are unavailable to the verification system 103 at a given time, i.e., that are external to a simulation the verification engineer desires to run at a given time, and not necessarily interfaces or components physically external to a final circuit design.

After selecting a node such as the node 106 in the circuit representation 102 connected to an external component such as external component 108 through an interface such as external interface 110, the verification system 103 uses aspects of the present disclosure in order to simulate performance of the circuit representation 102 without needing access to, or having to rely on accuracy of, the design of the external component 108. For example, even if the final design of the external component 108 is available, the verification engineer may desire to isolate a component of a final circuit in a simulation in order to ensure it is operating properly prior to running more complex simulations with additional components. However, to thoroughly verify the circuit of circuit representation 102 without relying on the actual final design of the external component 108, the verification system 103 needs to simulate functionality of the external component 108. In order to provide smart feedback in response to outputs of the circuit of circuit representation 102 at the node 106, the present disclosure provides simulated feedback 111 to the node 106 in accordance with a feedback representation 112 configured to emulate operation of the external component 108 and/or external interface 110.

In order to enable the verification system 103 to generate the simulated feedback 111 based on the feedback representation 112, in some embodiments, the emulation model 100 includes a control interface 114 usable to control operation of the feedback representation. In some embodiments, the control interface 114 is external to the circuit representation 102, as shown in FIG. 1, but in other embodiments the control interface 114 is wholly or partially included in the circuit representation 102. Generally, the control interface 114 enables the verification system 103 to enable or disable (bypass) smart feedback at desired nodes, such as the node 106, and/or to configure the associated feedback representation 112 to provide appropriate simulated feedback 111.

In some embodiments, the verification system 103 configures the feedback representation 112 based on a behavioral model 115 of the external component 108. In some embodiments, the behavioral model 115 includes statistical, heuristic, mathematical, and/or logical representations of the external component 108. For example, in some embodiments, the behavioral model 115 provides the feedback representation 112 with a functional model of a communications interface, a memory such as a cache, a co-processor, a data bus, or a storage device, among others, which performs full or partial emulation of the component it models. In some embodiments, the verification system 103 selects the behavioral model 115 from a prepopulated library, and, in some embodiments, a verification engineer configures the behavioral model 115 as needed for a specific component or specific test. In some embodiments, the verification system 103 configures the feedback representation 112 based on a machine learning model 116 of the external component 108. For example, in some embodiments, the feedback representation 112 updates a machine learning support matrix using supervised or unsupervised learning in response to arbitrary outputs from the node 106. In some embodiments, the machine learning model 116 includes, or a verification engineer configures the machine learning model 116 as a function of, one or more artificial neural networks, decision trees, linear regressions, logistic regressions, and/or support vector machines, among others.

In some embodiments, the verification system 103 configures the feedback representation 112 based on a virtualized component 118 of the external component 108. In some embodiments, the virtualized component 118 includes a logical abstraction of one or more pieces of hardware or software. For example, in some embodiments, the virtualized component 118 emulates an application, an operating system, a server or other computer, or a specific environment that the verification system 103 needs to perform a complete verification. In some embodiments, the verification system 103 configures the feedback representation 112 to produce errors, distortion, and/or random data 120 as required to ensure the robustness of the circuit of circuit representation 102. Thus, in some embodiments, the verification system 103 configures the feedback representation 112 to provide parity errors, introduce data distortions in re-transmission of data, and/or simulate packet or transmission drops or errors, among others, to provide exhaustive verification and, as a result, increase the security or reliability of a circuit of the circuit representation 102.

In some embodiments, the verification system 103 configures the feedback representation 112 with a programmable delay, programmable data, programmable addressing, or other protocol-specific attributes. In some embodiments, the verification system 103 configures the feedback representation 112 to operate in a burst mode, a continuous mode, or to provide a programmable number of reflections. In some embodiments, the verification system 103 configures the feedback representation 112 to use one or more addressing modes, such as swapping a destination and source address, or to use a programmable destination for reflected packets or responses. In some embodiments, the verification system 103 configures the feedback representation 112 to use one or more data response options, such as a random response within a set range, a noise signal, or a programmable data response. In some embodiments, the verification system 103 configures the feedback representation 112 to respond to programmable triggers based on an output of the circuit in circuit representation 102 at node 106, in some embodiments such that the feedback representation 112 only responds to the triggers with simulated feedback 111 while the feedback representation 112 is otherwise bypassed or merely inactive.

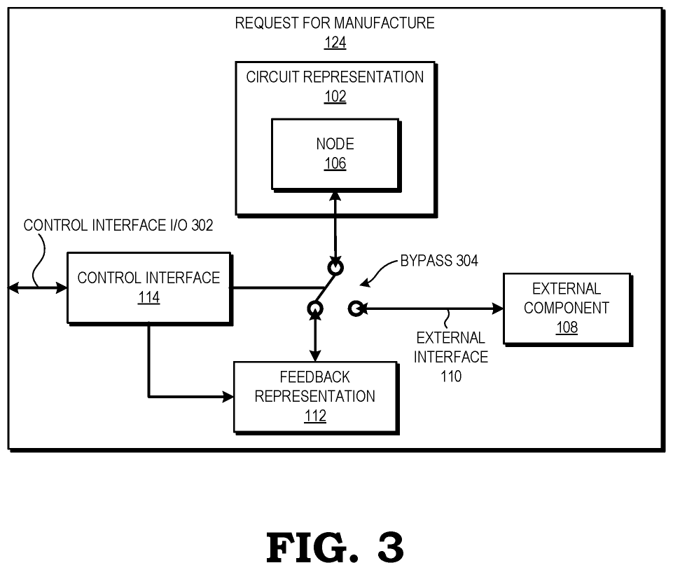

Accordingly, using aspects of the present disclosure, the verification system 103 configures the feedback representation 112 as needed via the control interface 114 in order to provide simulated feedback 111 at the node 106 when required, which enables the verification system 103 to simulate operation of the circuit in circuit representation 102 without needing to rely on the accuracy of an external component 108 or without even having access to a final design for the external component 108. Thus, by using an emulation model like emulation model 100, the verification system 103 simulates operation of elements of a final circuit design as components are developed or finalized without having to wait until every component is complete, which drastically reduces the traditional bottleneck created by delays in receiving final designs for various components. After a final circuit design is complete and the verification system 103 executes all required simulations and verifies that the circuit in circuit representation 102 performs as expected, in some embodiments, at block 212, the verification engineer and/or verification system 103 then includes the feedback representation 112 in a request for manufacture 124, as described further herein in connection with FIG. 3. Typically, the request for manufacture 124 is a digital file or set of files that a manufacturer uses to fabricate the circuit of circuit representation 102, although the request for manufacture 124 can take any form provided that a manufacturer can use it to fabricate the desired product.

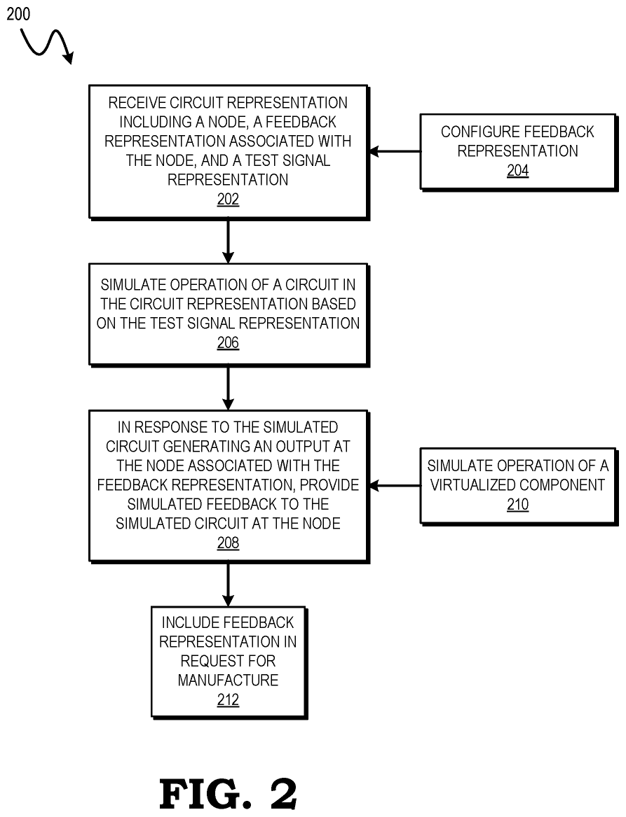

FIG. 2 illustrates an example method 200 for providing smart feedback in accordance with some embodiments. At block 202, a verification system such as the verification system 103 of FIG. 1 receives a circuit representation comprising a node, a feedback representation associated with the node, and a test signal representation. As discussed above with reference to FIG. 1, a verification engineer and/or the verification system 103 provides the circuit representation 102 and associates the feedback representation 112 with a node 106 of the circuit representation 102 in order to test operation of the circuit of the circuit representation 102. In some embodiments, the verification engineer and/or the verification system 103 selects or designs a specific test signal representation 104 in order to verify operation of the circuit in the circuit representation 102. In some embodiments, at block 204, as discussed above, the verification engineer and/or the verification system 103 also configures the feedback representation 112 to provide the desired simulated feedback 111. However, in other embodiments, the feedback representation 112 is preconfigured for testing a particular circuit in the circuit representation 102.

At block 206, the verification engineer causes the verification system 103 to simulate operation of the circuit in the circuit representation 102 based on the test signal representation 104. At block 208, in response to the simulated circuit in the circuit representation 102 generating an output at the node 106 associated with the feedback representation 112, the verification system 103 provides simulated feedback 111, such as one or more command responses, error messages, communication session negotiation messages, logical responses, and/or emulated circuit responses, among others, as discussed herein, to the simulated circuit in the circuit representation 102 at the node 106. In some embodiments, depending on whether and how the verification engineer and/or verification system 103 has configured the feedback representation 112, at block 210, the verification system 103 simulates operation of a virtualized component 118. After completing all required simulations and verifying that the circuit in circuit representation 102 performs as expected, in some embodiments, at block 212, the verification engineer and/or verification system 103 then includes the feedback representation 112 in a request for manufacture such as request for manufacture 124 of FIG. 1. In some embodiments, one or more portions of method 200 are automated, preconfigured, loaded, executed, or scripted as a function of instructions stored on a non-transitory computer readable medium or otherwise performed using automation.

FIG. 3 illustrates an example request for manufacture 124 in accordance with some embodiments. As discussed above, using aspects of the present disclosure, a verification engineer verifies circuit representations such as circuit representation 102 of FIG. 1 using a verification system such as verification system 103 of FIG. 1 without the need for final designs of an external component 108 or an external interface 110 or without having to rely on such final designs performing as expected. However, using aspects of the present disclosure, in some embodiments, even after fabrication of a circuit, such as the circuit of circuit representation 102, the verification engineer and/or the verification system 103 uses the same or similar aspects of the present disclosure to verify the actual operation of a circuit, such as the circuit of circuit representation 102, by including components such as one or more components of the emulation model 100 of FIG. 1 in a request for manufacture, such as the request for manufacture 124 of FIG. 3. For example, as shown in FIG. 3, in some embodiments, such a request for manufacture includes the circuit of circuit representation 102, the node 106, the external component 108, the external interface 110, and the control interface 114. Additionally, in the example of FIG. 3, the request for manufacture 124 includes a control interface input/output 302 (such as a port, a pin, or a communications module) and a bypass switch 304. In some embodiments, only one of the feedback representation 112 and the bypass switch 304 are included in a request for manufacture. In some embodiments, these additional components and/or other components are also included in the emulation model 100 of FIG. 1. As discussed above, the verification system 103 accesses the control interface 114 to control the feedback representation 112, and thus to control the simulated feedback 111 (FIG. 1) that the feedback representation 112 will provide to the node 106 in lieu of, or selectively overriding feedback from, the external component 108.

In some embodiments, the control interface input/output 302 is a pin operable to control bypass switch 304, in which case the control interface 114 and control interface input/output 302 are a single component. In other embodiments, as noted above, the control interface input/output 302 is a port, a pin, or a communications module, such that the verification system 103 can provide more complex signals and/or instructions to the feedback representation 112 in addition to controlling the bypass switch 304. For example, in some embodiments, the control interface 114 is a wireless interface and the control interface input/output 302 is an antenna, enabling the verification system 103 to wirelessly interact with the control interface 114. Generally, the control interface 114 and control interface input/output 302 can take any form that enables the verification system 103 to interact with the feedback representation 112 and/or bypass switch 304 as needed.

In some embodiments, the bypass switch 304 is controllably actuated through the control interface 114 and/or the feedback representation 112 in order to provide smart feedback in the form of simulated feedback 111 in accordance with the teachings of the present disclosure. Although shown as a switch in FIG. 3, in some embodiments, the bypass switch 304 is a multiplexer or any other suitable switching element. In some embodiments, the verification system 103 manually controls the bypass switch 304 by interacting with the control interface 114. In some embodiments, the verification system 103 configures the feedback representation 112, either in the details of the request for manufacture 124 or, after fabrication of, e.g., an integrated circuit in accordance with the request for manufacture 124, through control interface 114, to control the bypass switch 304. Thus, the bypass switch 304 is selectively controllable to, e.g., provide smart feedback via feedback representation 112 to enable a verification system to quickly verify the operation of the circuit of circuit representation 102, and then to bypass the feedback representation 112 and connect the node 106 of the circuit of circuit representation 102 directly to the external component 108 via external interface 110 to enable normal operation of the circuit of circuit representation 102 after verification is complete. An additional advantage of including the feedback representation 112, the control interface 114, the control interface input/output 302, and the bypass switch 304 in a request for manufacture such as request for manufacture 124 is that even after verification is complete and the bypass switch 304 has been switched to connect the node 106 of the circuit of circuit representation 102 with the external component 108 via external interface 110, if unexpected problems arise in the operation of the circuit of circuit representation 102 in normal operation (e.g., end-user use), a device containing the circuit can be returned to the manufacturer, and the manufacturer can more easily diagnose any problems that may be caused by the circuit in circuit representation 102 using techniques described hereinabove. Thus, in some embodiments, repair or diagnostic technicians use aspects of the present disclosure to diagnose potential problems in fabricated circuitry after it has been incorporated into a device and sold.

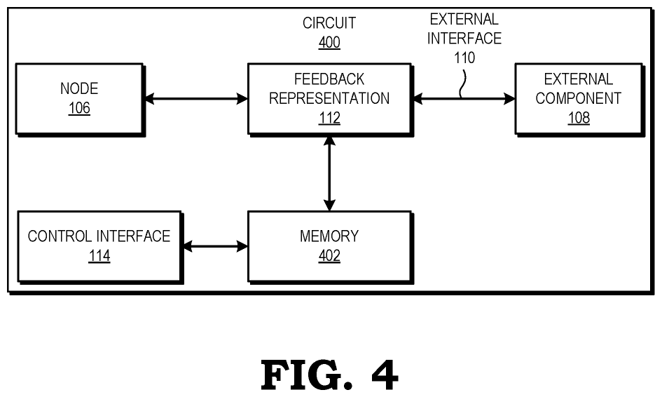

FIG. 4 illustrates an example smart feedback circuit in accordance with some embodiments. In some embodiments, the smart feedback circuit 400 is fabricated based on the request for manufacture 124 of FIG. 1. In the smart feedback circuit 400, the node 106, the external component 108, the external interface 110, the feedback representation 112, and the control interface 114 are similar to those described above in connection with FIG. 1, although they are arranged differently in FIG. 4. For example, in circuit 400, feedback representation 112 is interposed between the node 106 of the circuit 400 and the external component 108 along external interface 110. Using this configuration, the feedback representation 112 either intercepts signals from the node 106 to return smart feedback to the node 106 or, when selectively bypassed, allows signals from the node 106 to travel directly to the external component 108 via the external interface 110. For example, in some embodiments, the feedback representation 112 generates responses to probes, operation requests, and/or acknowledge requests. As discussed above, the control interface 114 enables a verification system such as the verification system 103 of FIG. 1 to enable or disable (bypass) smart feedback at desired nodes, such as the node 106, and/or to configure the associated feedback representation 112 to provide appropriate simulated feedback.

In order to configure the feedback representation 112 of the circuit 400, in some embodiments, a verification system programs a memory 402 connected with the feedback representation 112. In FIG. 4, the memory 402 is shown separately from the feedback representation 112, although in some embodiments the feedback representation 112 contains the memory 402. In some embodiments, the memory 402 is programmable and contains instructions or data for controlling the feedback representation 112 provided via the control interface 114, such as injected traces or a machine learning response matrix. In other embodiments, the memory 402 is preprogrammed such that control interface 114 is omitted from the circuit 400. When the control interface 114 is omitted, in some embodiments, the feedback representation 112 is activated based on predetermined signals from the node 106 or a predetermined operation of the circuit 400. For example, in some embodiments, the circuit 400 is configured into a test mode that activates the feedback representation 112 to selectively return smart feedback to the node 106 in response to a diagnostic signal received from the node 106 or an unexpected power cycle of the circuit 400. In some embodiments, the feedback representation 112 returns smart feedback to the node 106 for a set period of time after the circuit 400 is powered on to enable an initial diagnostic phase of a device containing the circuit 400, after which the feedback representation 112 automatically reverts to a bypass mode, enabling normal operation of the circuit 400 without smart feedback. Thus, the feedback representation 112 is enabled or disabled (bypassed) depending on desired functionality and, in some embodiments, for a preconfigured period of time.

In some embodiments, the techniques described above are implemented in a system including one or more integrated circuit (IC) devices (also referred to as integrated circuit packages or microchips), such as the smart feedback emulation model 100, the method 200 for providing smart feedback, the request for manufacture 124, and the smart feedback circuit 400 described above with reference to FIGS. 1-4. Electronic design automation (EDA) and computer aided design (CAD) software tools may be used in the design and fabrication of these IC devices. These design tools typically are represented as one or more software programs. The one or more software programs include code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any non-transitory storage medium, or combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

In some embodiments, certain aspects of the techniques described above may implemented by one or more processors of a processing system executing software. The software includes one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A method comprising:
receiving a circuit representation comprising a node and a feedback representation associated with the node;
simulating operation of a circuit in the circuit representation; and
in response to the simulated circuit generating an output at the node associated with the feedback representation, providing simulated feedback to the simulated circuit at the node.

2. The method of claim 1, wherein the node is located at an external interface of the circuit representation.

3. The method of claim 2, wherein the external interface is an intra-die, inter-die, stack-to-stack, or socket-to-socket interface.

4. The method of claim 1, wherein providing simulated feedback to the simulated circuit at the node further comprises simulating operation of a virtualized component.

5. The method of claim 1, wherein the simulated feedback is based on the feedback representation, the method further comprising configuring the feedback representation to control the simulated feedback.

6. The method of claim 5, wherein configuring the feedback representation comprises configuring the feedback representation based on a behavioral model or a machine learning model.

7. The method of claim 5, wherein configuring the feedback representation comprises configuring the feedback representation to produce errors, distortions, or random data in the simulated feedback.

8. The method of claim 5, wherein the circuit representation includes a control interface operable to configure the feedback representation, the method further comprising including the feedback representation and the control interface in a request for manufacture of the circuit representation.

9. The method of claim 8, wherein the control interface is operable to selectively bypass the feedback representation.

10. The method of claim 1, further comprising including the feedback representation in a request for manufacture of the circuit representation.

11. A non-transitory computer readable medium embodying a set of executable instructions, the set of executable instructions to manipulate at least one processor to:
receive a circuit representation comprising a node and a feedback representation associated with the node;
simulate operation of a circuit in the circuit representation; and
in response to the simulated circuit generating an output at the node associated with the feedback representation, provide simulated feedback to the simulated circuit at the node.

12. The non-transitory computer readable medium of claim 11, wherein the node is located at an external interface of the circuit representation.

13. The non-transitory computer readable medium of claim 12, wherein the external interface is an intra-die, inter-die, stack-to-stack, or socket-to-socket interface.

14. The non-transitory computer readable medium of claim 11, wherein the instructions for providing simulated feedback to the simulated circuit at the node include instructions for simulating operation of a virtualized component.

15. The non-transitory computer readable medium of claim 11, wherein the simulated feedback is based on the feedback representation, the instructions further comprising instructions for configuring the feedback representation to control the simulated feedback.

16. The non-transitory computer readable medium of claim 15, wherein the instructions for configuring the feedback representation comprise instructions for configuring the feedback representation based on a behavioral model or a machine learning model.

17. The non-transitory computer readable medium of claim 15, wherein the circuit representation includes a control interface operable to configure the feedback representation, the instructions further comprising instructions for including the feedback representation and the control interface in a request for manufacture of the circuit representation.

18. The non-transitory computer readable medium of claim 17, wherein the control interface is operable to selectively bypass the feedback representation.

19. The non-transitory computer readable medium of claim 11, wherein the instructions further comprise instructions for including the feedback representation in a request for manufacture of the circuit representation.

20. An emulation model comprising:
a circuit representation comprising a node; and
a feedback representation associated with the node of the circuit representation, wherein the feedback representation is configured to provide feedback to a circuit in the circuit representation in response to the circuit generating a signal at the node.
